(19) United States
(12) Patent Application Publication
(10) Pub. No.: US 2005/0266620 A1
(43) Pub. Date: Dec. 1, 2005

(54) Semiconductor device, electro-optic device, integrated circuit, and electronic apparatus

(75) Inventor: Yasushi Hiroshima, Suwa-shi (JP)

Correspondence Address: BANNER & WITCOFF, 1001 G STREET N W, SUITE 1100, WASHINGTON, DC, 20001, US

(73) Assignee: Seiko Epson Corporation, Shinjuku-ku (JP)

(21) Appl. No.: 11/136,389

(22) Filed: May 25, 2005

(30) Foreign Application Priority Data
May 26, 2004 (JP) 2004-156534(P)

(51) Int. Cl. H01L 21/00; H01L 21/84; H01L 31/119; H01L 31/113; H01L 31/062; H01L 29/94; H01L 29/76

(52) U.S. Cl. 438/151; 257/295

(57) ABSTRACT

The present invention is directed to a semiconductor device with a thin film transistor on a substrate and a method of forming that semiconductor device and thin film transistor on a substrate. The thin film transistor on the substrate is created by forming a starting point section to be an origin of crystallization of a semiconductor film on the substrate. The semiconductor film is then formed on the substrate originally provided with the starting point. Heat treatment is executed on the semiconductor film to form a substantially single crystal grain having a substantially centered starting point. The semiconductor film is patterned to form a transistor region and a thin film transistor is formed with by forming a gate insulation layer and the gate electrode on the transistor region. The thickness of the semiconductor film of the thin film transistor is less than or equal to 1/7 of the channel length.

### RELATED APPLICATION INFORMATION

This application claims priority to Japanese Application No. 2004-156534, filed May 26, 2004, whose contents are expressly incorporated herein by reference.

### FIELD OF THE INVENTION

1. Technical Field

Aspects of the present invention relate to a method of manufacturing a semiconductor device and the semiconductor device manufactured by the method, along with electro-optic devices, integrated circuits, and other such electronic apparatuses incorporating the semiconductor device.

2. Related Art

In electro-optic devices such as liquid crystal display devices or organic EL (electroluminescence) display devices, pixel switching can be performed using thin film circuits composed of thin film transistors as semiconductor elements. In conventional thin film transistors, active regions such as channel forming regions may be formed with amorphous silicon or polycrystalline silicon films. Use of polycrystalline silicon films may improve electrical characteristics such as mobility when compared with those made with amorphous silicon films, thus providing improved performance of thin film transistors.

In order to further improve performance of thin film transistors, a method of forming a semiconductor film with large crystal grains to prevent grain boundaries from entering the channel regions of the thin film transistors has been studied. For example, as described in, “Single Crystal Thin Film Transistors; IBM TECHNICAL DISCLOSURE BULLETIN August 1993 pp. 257-258”, or “Advanced Excimer-Laser Crystallization Techniques of Si Thin-Film For Location Control of Large Grain on Glass; R. Ishihara et al., proc. SPIE 2001, vol. 4295 pp. 14-23”, a semiconductor film may be crystallized using a microscopic opening and provided to a substrate, as a starting point of crystal growth to form large sized silicon crystal grains.

Thin film transistors using the silicon film of the large sized grains formed by this technology can prevent entry of the grain boundaries into the single thin film transistor forming area, particularly the channel forming area. Thus, thin film transistors with superior electronic characteristics such as mobility can be obtained.

The silicon grains can include coincidence site lattice (CSL) grain boundaries such as Σ=3, Σ=9, or Σ=27, but also can be regarded as so-called substantially single crystal grains that exclude random grain boundaries. CSL grain boundaries do not form trap states around deep energy levels around the mid-gap in the energy band gaps of silicon. Therefore, the effects on the electrical characteristics, especially the sub threshold characteristics of the thin film transistor, formed with CSL grain boundaries may be minimal. However, since the CSL grain boundary is a type of crystal defect, the number of the CSL grain in boundaries included in a substantially single crystal grain is preferably minimized in view of the variation and stability of the electrical characteristics of the thin film transistors. It has been realized that as the silicon film thickness increases, the number of CSL grain boundaries in a substantially single crystal grain decreases and the number of grains with a relatively larger grain size increases. It therefore is possible to form a single or a plurality of thin film transistors within a substantially single crystal grain, or form stable thin film transistors with excellent characteristics.

Further, scaling technologies have progressed in the thin film transistor field, including technologies for forming microscopic thin film transistors with channel lengths no greater than 1 μm as described in “0.5 μm-Gate Poly-Si TFT Fabrication on Large Glass Substrate,” C. Iriguchi et al., AM-LCD 03, pp. 9-12. Scaling down of thin film transistors improves the characteristics of thin film transistors by allowing increased ON current and enhancing circuit integration.

However, problems currently exist in scaling down thin film transistors if the scaling down simply reduces the channel length with the remaining silicon film thicker than a certain level. For example, this scaling down creates a break down voltage between the source and the drain that is lowered by the short channel effect, thus disabling the thin film transistor and preventing its use in a circuit.

### SUMMARY OF INVENTION

Therefore, an aspect of the present invention is to provide a method of manufacturing a semiconductor device, capable of obtaining a high performance thin film transistor having sufficient break down voltage between the source and the drain.

In order to obtain aspects of the present invention, a method of manufacturing a semiconductor device for forming a thin film transistor on a substrate having at least one insulation surface using a semiconductor film is needed. Generally, this method may include: forming a starting point section for originating crystallization of the semiconductor film; forming the semiconductor film with a thickness of t from the starting point; executing a heat treatment on the semiconductor film to form a substantially single crystal grain having a substantially centralized starting point; patterning the semiconductor film to form a transistor region which may be used as a source region, a drain region, or a channel forming region; and forming a thin film transistor with a channel length of L by forming a gate insulation layer and the gate electrode on the transistor region. In this method, the semiconductor film and the gate electrode are generally formed so that the relationship between the thickness t of the semiconductor film and the channel length L satisfy the inequality of: 7*t≦L.

According to the above method, the substantially single crystal grain, which may be a high-performance semiconductor film, generally may be formed using the starting point section as the origin. Use of the starting point section as the origin generally allows the thickness of the film to be less than or equal to a predetermined portion of the channel length of the thin film transistor. According to aspects of the invention, adjusting the thickness of the semiconductor film and the channel length while maintaining the above relationship, allows the thickness of the semiconductor film to vary in order to counteract or eliminate the short channel effect that may cause the break down voltage between the source and the drain to, and thus form a thin film transistor capable of realizing high-performance and stable circuit operations.

Another aspect of the present invention is a semiconductor device composed of a thin film transistor formed using a semiconductor film formed on a substrate, wherein the semiconductor film generally includes a substantially single crystal grain formed using an originating starting point section provided on the substrate, and the channel length L of the thin film transistor is patterned so as to satisfy the following inequality with respect to the thickness t of the semiconductor film: 7*t≦L. The semiconductor device may be manufactured by, for example, the method of manufacturing the semiconductor device as described above, by arranging the thickness t of the semiconductor film to be no greater than a predetermined thickness with respect to the channel length L, in order to maintain the break down voltage between the source and the drain thus avoiding short channel effects and enabling formation of a thin film transistor with excellent electrical characteristics.

### BRIEF DESCRIPTION OF THE DRAWINGS

Aspects of the invention are described with reference to the accompanying drawings, wherein like numbers reference like elements.

FIGS. 1A through 1E are illustrative diagrams for a process according to aspects of the present invention.

FIG. 2 is an illustrative diagram for a process according to aspects of the present invention.

FIGS. 3A and 3B are illustrative diagrams for explaining relationships between arrangements of microscopic openings and shapes of the substantially single silicon grains formed in accordance to aspects of the present invention.

FIG. 4 is an illustrative diagram of a thin film transistor's gate electrode and activated regions (a source region, a drain region, and a channel forming region) according to aspects of the present invention.

FIGS. 5A through 5C are illustrative diagrams for a process of forming a thin film transistor according to aspects of the present invention.

FIG. 6 is an illustrative diagram for characteristics of a thin film transistor formed according to aspects of the present invention.

FIG. 7 is an illustrative diagram of an electro-optic device according to aspects of the present invention.

FIGS. 8A through 8F are illustrative diagrams of electronic equipment according to aspects of the present invention.

### DETAILED DESCRIPTION OF THE INVENTION

Hereinafter, an illustrative embodiment for putting the present invention into practice is described with reference to the accompanying drawings. It is noted that various connections are set forth between elements in the following description. It is noted that these connections in general and, unless specified otherwise, may be direct or indirect and that this specification is not intended to be limiting in this respect.

The manufacturing method according to aspects of the present invention generally may include the step of forming microscopic openings on a substrate, the microscopic openings being hollow sections, which may become starting points of crystallization of silicon films; and forming the semiconductor films which may generally include the step of growing and forming silicon grains from the microscopic openings; and the step of forming a thin film transistor with the silicon films including the silicon grains. The semiconductor films according to aspects of the present invention may be composed of any material known to those of ordinary skill. According to aspects of the present invention, the semiconductor film is preferably a polycrystalline semiconductor film or an amorphous semiconductor film.

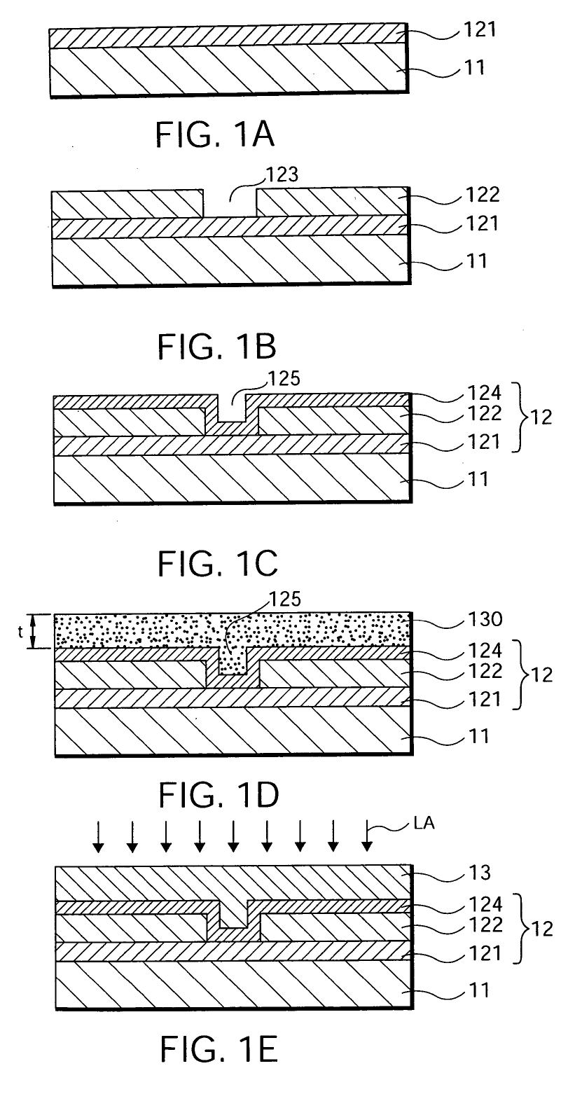

As shown in FIG. 1A, a silicon oxide film 121 is formed on the glass substrate 11 as a priming insulation film. The thickness of the film can generally be about 200 nm. Subsequently, a silicon oxide film is formed on the priming insulation film 121 with a thickness generally about 550 nm as a first insulation film 122. The first insulation film 122 is provided with an opening 123 with a diameter of generally about 1 μm (FIG. 1B). It can be formed by executing the steps known to those of ordinary skill in the art for providing the opening 123. An illustrative method of providing opening 123 includes forming a photoresist film (not shown in the drawings) having openings for exposing areas where the openings 123 are to be formed on the first insulation film 122 and then exposing and developing the photoresist film coated on the first insulation film 122 using a mask. Reactive ion etching may then be used on the photoresist film as an etching mask to subsequently remove the photoresist film. After removal of the photoresist film, a second insulation film 124, may be formed on the first insulation film 122 including the openings 123 (FIG. 1C). Any material known to those of skill in the art that is suitable for use as a second insulation film may be used; preferably this material is a silicon oxide film. According to aspects of the invention, the diameter of the opening 123 can be narrowed by adjusting the deposition thickness of the second insulation film 124 to obtaining a microscopic opening 125 with a diameter of generally about 20 nm through about 150 nm as the hollow section.

Each of the priming insulation film 121, the first insulation film 122, and the second insulation film 124 (also referred to as an insulation layer 12) can be formed using methods known to those of ordinary skill in the art. Generally, a PECVD process may be used. Preferably, a PECVD process using TEOS (Tetra Ethyl Ortho Silicate) or silane (SiH₄) gas as a material is used to form one or more of films 121, 122, and 124.

As shown in FIG. 1D, an amorphous semiconductor film 130 to be used is formed on the silicon oxide film, which is the second insulation film 124, and inside the microscopic openings 125 using a film forming process. Preferably, the semiconductor film 130 is an amorphous silicon film. Generally, the film forming process used in accordance with aspects of the present invention may be any of the film forming processes known to those of ordinary skill. Preferably, the film forming process is a LPCVD process or a PECVD process. Generally, the amorphous silicon film 130 is formed to have the thickness t (μm). Preferably, the thickness t of the amorphous silicon film 130 is from about 0.05 to about 0.3 μm. Even more preferably, the film thickness t satisfies the following inequality 7*t≦L with respect to the channel length L (μm) in a thin film transistor forming process according to aspects of the present invention. Alternatively, according to another aspect of the present invention, the film can be deposited with a thickness t that does not satisfy the inequality 7*t≦L, and thereafter thinned by any of the methods well known to those of ordinary skill such that film thickness t satisfies the inequality. 7*t≦L.

In other aspects of the present invention, a polycrystalline silicon film may be substituted for the amorphous silicon film 130 or silicon film 13. In the aspects of the invention in which silicon films 13 may be formed by the LPCVD process or the PECVD process, the content of hydrogen in the obtained silicon films 13 may result in a silicon film 13 with inadequate physical properties that results in ablation of the silicon film 13 during subsequent processing steps (e.g., laser irradiation). In aspects of the invention using a silicon film 13, heat treatment, using any of the methods known to those of ordinary skill is executed on the silicon film to generally reduce the content of hydrogen prior to any further processing steps. Preferably, the content of hydrogen is reduced to no greater than 1% in the silicon film.

In other aspects of the invention, the starting point section for single crystal growth is preferably a hollow section provided to the substrate. If the hollow section is provided, the crystal growth starts from the bottom of the hollow section during the heat treatment process. In this case, the diameter of the hollow section is preferably equal to or smaller than the grain diameter of a single crystal grain of a polycrystalline semiconductor that starts its crystal growth from the bottom of the hollow section.

As shown in FIG. 1E, laser irradiation may be executed on the silicon film 13. Generally the conditions of laser irradiation are sufficient so that a substantial amount of the laser irradiation is absorbed at or near the surface of the silicon film. Preferably, laser irradiation is executed using an XeCl pulse excimer laser having a wave length of 308 nm and a pulse width of about 20 to about 30 ns or an XeCl excimer laser having a pulse width of 200 ns with an energy density of about 0.4 through about 2.0 J/cm2. Even more preferably, the laser irradiation described above, uses a XeCl excimer laser with a long pulse width.

Proper selection of laser irradiation conditions generally places the silicon film in condition where a part at the bottom of microscopic openings 125 remains solid and the remaining parts thereof are substantially melted. Silicon crystal growth after laser irradiation begins in the silicon film that remained solid during laser irradiation and propagates itself through the melted silicon film to the vicinity of the surface of the silicon film 13. In other aspects of the invention, sufficient energy density of the laser irradiation is provided so that no part of silicon film 13 remains solid. In these aspects of the invention, silicon crystal growth begins in the silicon film at or near the bottom of microscopic opening 125 due to a temperature difference between the vicinity of the surface of the silicon film 13 and the bottom of the microscopic openings 125 Silicon crystal growth in this aspect of the invention also continues through the melted silicon to the vicinity of the surface of the silicon film 13.

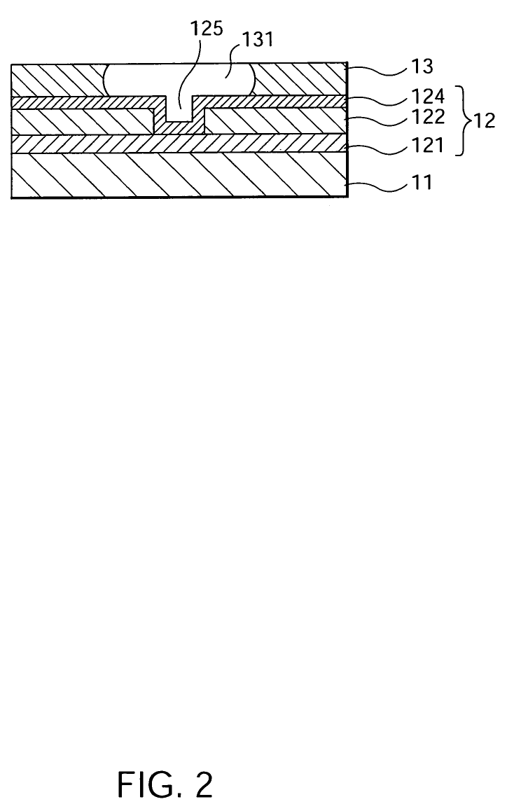

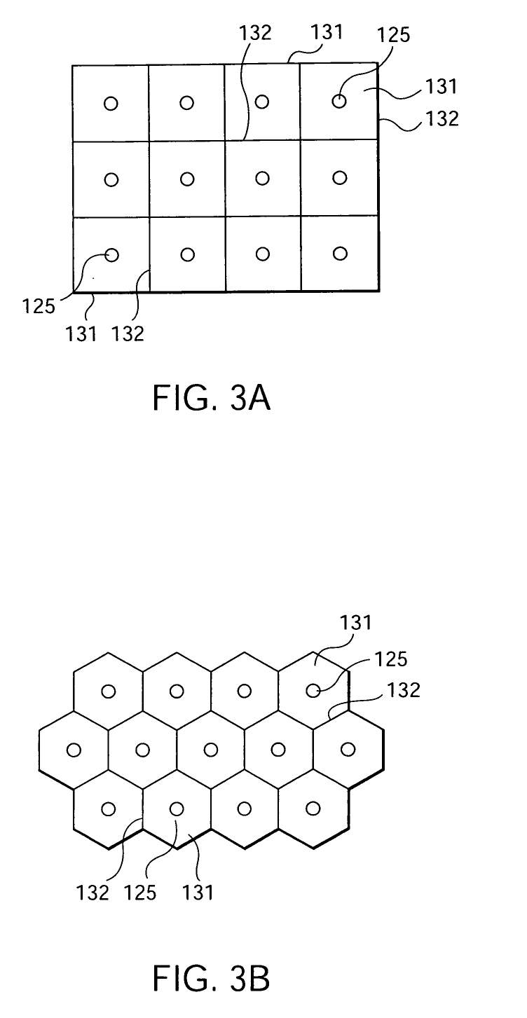

During early stages of the silicon crystal growth, some crystal grains can be generated at the bottom of the microscopic openings 125. In this case, if the cross-sectional size (the diameter of the hole in one embodiment according to aspects of the invention) of the microscopic opening 125 is almost the same as or slightly smaller than that of a single crystal grain, only a single crystal grain can reach the upper section (opening section) of the microscopic opening 125. Accordingly, in the almost completely melted part of the silicon film 13, as shown in FIG. 2, crystal growth proceeds from the single crystal grain reaching the upper part of the microscopic opening 125, and as shown in FIGS. 3A and 3B, the crystal growth may form a silicon film with large grain sized, substantially single silicon grains 131 arranged regularly, each of the silicon grains having the microscopic opening as the substantial center thereof.

In other aspects of the invention, the substantially single silicon grains denote those that can include CSL grain boundaries (coincidence grain boundaries) such as Σ=3, Σ=9, or Σ=27, but do not include any random grain boundaries. In general, random grain boundaries include a lot of silicon unpaired electrons that may contribute to degradation or variation of the characteristics of a thin film transistor formed thereon. Since the substantially single silicon grains formed by some aspects of the present invention have substantially fewer random grain boundaries, a thin film transistor having superior characteristics can be obtained by forming the thin film transistor within the substantially single crystal grain. Once the microscopic opening 125 has a diameter (or cross sectional length for some aspects of the invention where microscopic opening 125 is not substantially circular) larger than about 150 nm, some crystal grains generated at the bottom of the microscopic opening 125 can grow to reach the upper portion of the microscopic opening, resulting in random grain boundaries in the silicon grain grown with the microscopic opening 125 as the substantial core.

It is generally preferred that the glass substrate is heated during the laser irradiation. Preferably this heating process is executed with a stage for mounting the glass substrate so that the temperature of the glass substrate is kept in a range from about 200° C. to about 400° C. The heating of the substrate may enlarge the grain size of each of the substantially single silicon grains 131 by about 1.5 to about 2.0 times. Additionally, simultaneous heating decreases the speed of the crystal growth and the crystallinity of the substantially single silicon grains 131 is advantageously improved. The combination of laser irradiation of microscopic openings 125 at desired portions on the glass substrate 11, can lead to substantially single silicon grains 131 with relatively superior crystallinity being formed after the laser irradiation using the microscopic openings 125 as the substantial cores

In some aspects of the present invention where an amorphous silicon film having a thickness that does not satisfy the inequality 7*t≦L, is deposited, a process for thinning the substantially single silicon grains 131 is executed after the crystallization by the laser irradiation.

Generally the thinning of the silicon film uses a heat resistant substrate. Preferably, the heat resistant substrate is quartz. Any of the thinning methods known to those of ordinary skill may be used in this aspect of the present invention. In one aspect of the invention thermal oxidization of the surface of the substantially single silicon grain 131 is performed followed by etching with hydrofluoric acid or other suitable compounds known to those of ordinary skill. Alternatively, another aspect of the invention uses mechanical and chemical grinding of the surface of the substantially single silicon grain 131 so as to thin it. Preferably, this aspect of the invention uses a CMP (Chemical and Mechanical Polishing) method that, in addition to reducing the thickness of the substantially single silicon grains 131 formed on the substrate to satisfy the inequality, 7*t≦L, also causes the surface of the substantially single silicon grains 131 to be substantially planar.

Other aspects of the invention are directed to a thin film transistor formed from the above-described silicon film and a method of making such thin film transistors. Generally, the crystal grain diameter of the substantially single silicon grains 131 obtained by crystallization using the microscopic openings 125 as the origins depends on the thickness of the silicon film 13 or the energy density of the laser irradiation. Preferably those diameters do not exceed from about 6 to about 7 μm.

Thin film transistors generally have multiple single silicon grains 131 obtained by using microscopic openings 125 as their origins. Preferably, the relationship between arrangements of the microscopic openings 125 and the shapes of the substantially single silicon grains 131 result in contact of the substantially single silicon grains. As shown in FIG. 3A, a plurality of the microscopic openings 125 are disposed with an interval equivalent to or smaller than the diameter of the crystal grains, thus enabling formation of a plurality of the substantially single silicon grains 131 in contact with each other. Generally, any of the methods known to those of ordinary skill can be adopted for disposing the microscopic openings 125. Preferably, the microscopic openings 125 are disposed to have a constant interval in both horizontal and vertical directions as shown in FIG. 3A, or a constant interval to all adjacent microscopic openings 125 as shown in FIG. 3B. In the preferred pattern of microscopic openings 125 shown in FIG. 3A, the resulting substantially single silicon grains 131 generally have square shapes. In the preferred pattern of microscopic openings 125 shown in FIG. 3B, the substantially single silicon grains 131 generally have hexagonal shapes.

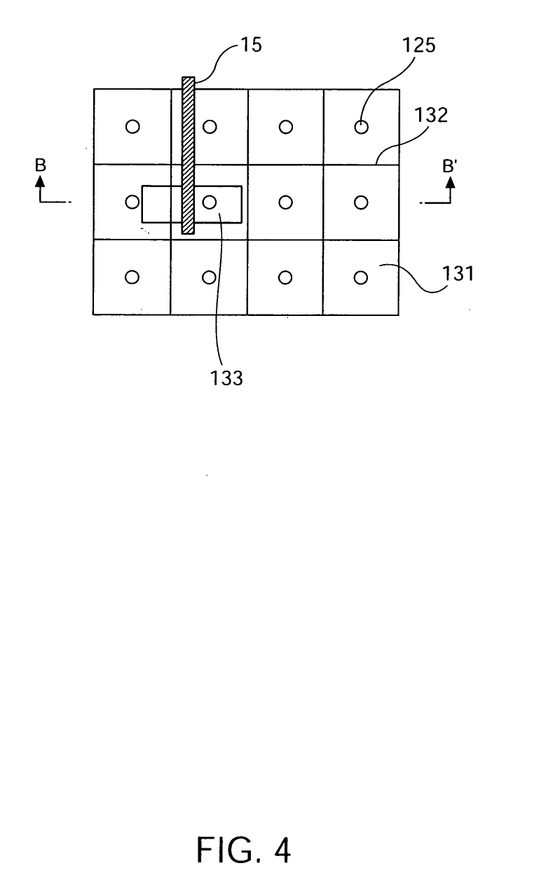

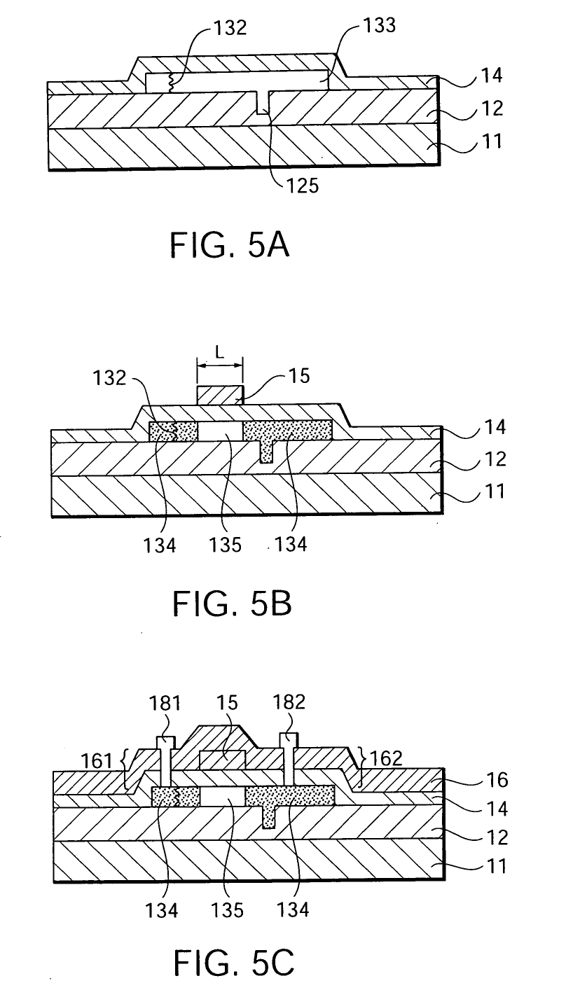

Generally the thin film transistor according to some aspects of the invention may be formed using any method known to those of ordinary skill using silicon film 13 as a starting material. Preferably, the method results in a thin film transistor T as shown in FIGS. 4, and 5A through 5C. FIG. 4 shows a plan view of the completed thin film transistor while FIGS. 5A through 5C show cross-sectional views thereof along the B-B′ direction shown in FIG. 4.

Generally, a method of forming the thin film transistor according to some aspects of the invention may execute a patterning process on the silicon film having a plurality of the substantially single silicon grains 131 preferably aligned as shown in FIG. 3A or 3B. As shown in FIG. 4, the patterning is preferably executed so as to remove unnecessary portions of the silicon film. In these aspects, portions of the thin film transistor that form a channel forming region 135 may be preferably arranged to exclude many CSL grain boundaries distributed in or around the microscopic openings 125. Additionally, the substantially single crystal grains are preferably disposed in portions to be the source region or the drain region 134, especially in a part of source region or the drain region 134 corresponding to the area where the contacting hole is later provided.

As shown in one aspect of the invention in FIG. 5A, a second insulation film, silicon oxide film 14, is formed on the upper surface 12 of the silicon oxide film 124, and the patterned silicon film 133 by any of the methods known to those of ordinary skill. Preferably, an electron cyclotron resonance PECVD (ECR-PECVD), parallel plate PECVD, or other similar process, is used. This silicon oxide film 14 functions as a gate insulation film of the thin film transistor. Generally the thickness of the silicon oxide film 14 is sufficient to perform the function of a gate insulation film. Preferably silicon oxide film 14 has a thickness of about 10 nm to about 150 nm.

As shown in one aspect of the invention in FIG. 5B, a gate electrode 15 and a gate wiring film are formed so as to have a channel length of L (μm) by patterning a metal thin film made of tantalum, aluminum, or other similar metals using any film forming process known to those of ordinary skill. Preferably the thin film forming process is a sputtering process. Subsequently, the source region, the drain region 134, and the channel forming region 135 are formed in the silicon film 133 by executing a self-aligning ion implantation in which impurity elements acting as the donors or the acceptors are implanted using the gate electrode 15 as a mask. Phosphorous (P) may be implanted as the impurity element, and a heat treatment can then be executed under temperature of about 450° C. to recover the crystallinity of the silicon grains damaged by the impurity implantation and also to activate the impurity element.

As shown in FIG. 5C, a silicon oxide film 16 may be formed on the upper surface of the silicon oxide film, which is the gate insulation film 14, and the gate electrode 15 using any film forming process known to those of ordinary skill. Preferably, the silicon-oxide film 16 is formed using a PECVD process. This silicon oxide film 16 functions as an interlayer insulation film and generally of a thickness sufficient to perform this function. Preferably, silicon-oxide layer 16 is about 500 nm thick. Subsequently, contact holes 161, 162, respectively reaching the source region and the drain region through the interlayer insulation film 16 and the gate insulation film 14, may be formed. Subsequently, source electrode 181 and the drain electrode 182 may then be formed by patterning after filling these contact holes with metal such as aluminum or tungsten using any film forming process known to those of ordinary skill, preferably a sputtering process.

In some aspects of the present invention, the substantially single silicon grains 131 grown from the microscopic openings 125 can also be disposed on portions of the silicon film 133 positioned at areas contacting holes 161, 162 and contacting the source electrodes 181 or the drain electrodes 182 to improve electrical connections between the source electrode 181 or the drain electrode 182 (e.g., a metal film) and the silicon film 133.

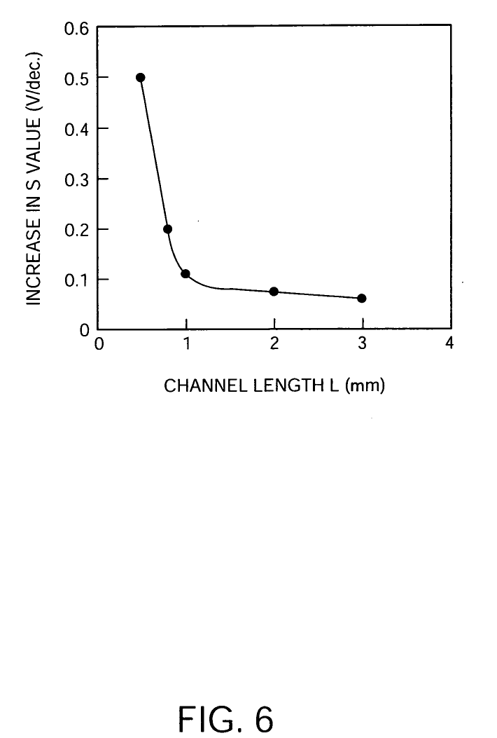

FIG. 6 shows an example of characteristic data of a thin film transistor formed according to aspects of the present invention in comparison to characteristic data of other thin film transistors. The thickness t (μm) of the silicon film 133 in the thin film transistor is 0.15 μm, the horizontal axis of the graph denotes the channel length L (μm), and the vertical axis thereof denotes increase in the S value (V/dec.), the gradient of the sub threshold characteristics while changing the voltage between the source and the drain from 0V to 3V. As shown in FIG. 6, in the thin film transistor that satisfies the inequality 7*t≦L and has a channel length more than about 1 μm, provides breakdown voltage sufficient with respect to the voltage applied between the source and the drain, and the increase in the S value is substantially reduced when compared to thin film transistor that do not satisfy the inequality 7*t≦L. The thin film transistors that do not satisfy the inequality exhibit punch through between the source and the drain, and accordingly, an increase in the drain current corresponding thereto and increase in the S value is evident. Such reduction in breakdown voltage causes abnormal operations of the device implementing the thin film transistor.

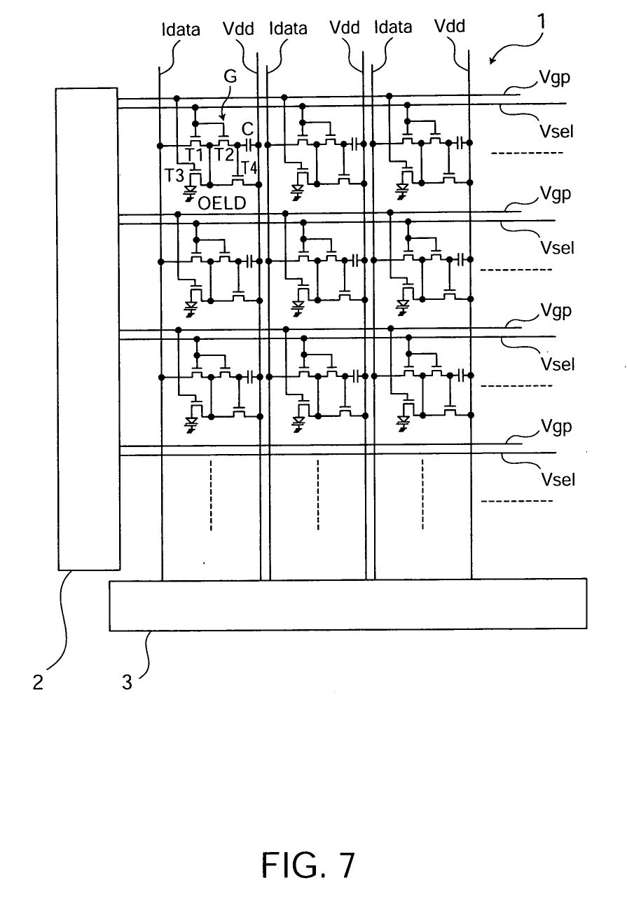

In other aspects of the invention, the above thin film transistor may be applied as a switching element for a liquid crystal display device or a drive element for an organic EL display device. FIG. 7 is a view showing a connection scheme of a display device 1 as one example of an electro-optic device according to some aspects of the present invention. As shown in FIG. 7, the display device 1 is configured to have pixel areas G disposed inside the display area. The pixel area G uses above described thin film transistors T1 through T4 for driving organic EL light emitting elements OELD. A light emission control line Vgp and a write control line Vsel are supplied from a driver region 2 to each of the pixel areas G. From the driver region 3, a current line Idata and a power supply line Vdd are supplied to each of the pixel areas G. Current programming to each of the pixel areas G is executed by controlling the write control line Vsel and the constant current line Idata, and by controlling the light emission control line Vgp, light emission is controlled. Further, the thin film transistors according to aspects of the present invention can be used as transistors composing the driver region 2 or 3. Preferably the thin film transistors according to aspects of the invention may be it is advantageously used in circuits requiring large current capacity such as buffer circuits for selecting the light emission control line Vgp and the write control line Vsel included in the driver region 2 or 3.

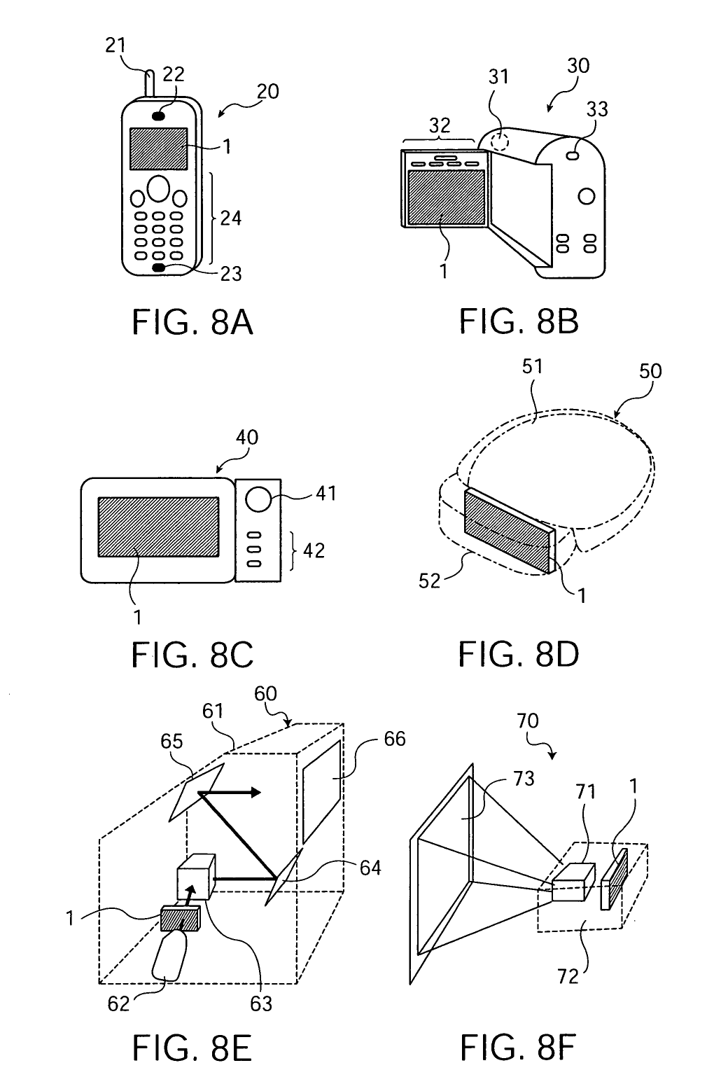

FIGS. 8A through 8F are views for showing examples of electronic equipment which can apply the display device 1 according to aspects of the invention. The incorporation of display device 1 according to aspects of the invention may be incorporated in various electronic equipment well known to those of ordinary skill.

FIG. 8A shows an application example to a mobile phone, in which the mobile phone 20 is equipped with an antenna section 21, an audio output section 22, an audio input section 23, an operating section 24, and the display device 1 according to aspects of the present invention. As described above, the display device 1 according to an aspect of the present invention can be applied as the display section of the mobile phone.

FIG. 8B shows an application example to a video camera, in which the video camera 30 is equipped with a receiver section 31, an operating section 32, an audio input section 33, and a display device 1 according to aspects of the present invention. As described above, the display device 1 according to an aspect of the present invention can be utilized as a finder or a display section of a video camera, a digital camera, or the like.

FIG. 8C shows an application example to a mobile personal computer (so-called PDA), in which the computer 40 is equipped with a camera section 41, an operating section 42, and a display device 1 according to aspects of the present invention. As described above, the display device 1 according to an aspect of the present invention can be applied as a display section of a computer device.

FIG. 8D shows an application example to a head mount display, in which the head mount display 50 is equipped with a band 51, an optical system housing section 52, and the display device 1 according to aspects of the present invention. As described above, the display device 1 according to an aspect of the present invention can be applied as an image display source of a head mount display or the like.

FIG. 8E shows an application example to a rear projector, in which the rear projector 60 is equipped with a light source 62, an optical system 63 for recombination, mirrors 64, 65, a screen 66, and the display device 1 according to aspects of the present invention in a chassis 61. As described above, the display device 1 according to an aspect of the present invention can be applied as an image display source of a rear projector.

FIG. 8F shows an application example to a front projector, in which the front projector 70 is equipped with an optical system 71 and the display device 1 according to aspects of the present invention in a chassis 72 so as to be able to display images on a screen 73. As described above, the display device 1 according to an aspect of the present invention can be applied as an image display source of a front projector.

The display device 1 using the transistor according to some aspects of the present invention can be applied, not only to the examples described above, but also to any electronic equipment capable of using a liquid crystal display device or an organic EL display device of the active type or passive type. Other illustrative electronic devices include, but are not limited to, facsimile machines having a display function, viewfinders of digital cameras, televisions, electronic notepads, electronic bulletin boards, or other electronic advertisement displays.

Another aspect of the present invention generally combines the method of manufacturing a thin film transistor described above with any component transfer technology known to those of ordinary skill in the art. Preferably, after forming a semiconductor device on a first substrate, which becomes a transfer origin, the semiconductor device is then transferred to a second substrate, which becomes a transfer destination. Thus, a first substrate having suitable conditions (e.g., shape, size, physical characteristics) for formation of fine and high performance semiconductor films or elements formation can be used, as the first substrate. Further, the second substrate, since no restriction from the process for forming the element exists, can use a large sized substrate of a desired material that can be selected from a wide variety of alternatives such as an inexpensive substrate made of synthetic resin or soda glass, or a plastic film having elasticity. Therefore, it becomes possible to easily (with low cost) form the fine and high performance thin film semiconductor elements in a substrate with a large area.

1. A method of manufacturing a thin film transistor on a substrate having at least one insulation surface comprising:
forming a starting point section to be an origin of crystallization of a semiconductor film;
forming the semiconductor film with a thickness of t;
executing a heat treatment on the semiconductor film patterning the semiconductor film; and
forming a thin film transistor with a channel length by forming a gate insulation layer and a gate electrode on the transistor region,
wherein, the thickness of the semiconductor film is less than or equal to 1/7 of the channel length.

2. The method according to claim 1, wherein the starting point is a hollow section provided to the substrate.

3. The method according to claim 1, wherein the step of executing the heat treatment comprises laser irradiation.

4. The method according to one of claim 2, wherein the step of executing the heat treatment comprises laser irradiation.

5. A semiconductor device comprising
a thin film transistor formed using a semiconductor film formed on a substrate, wherein the semiconductor film comprises a substantially single crystal grain formed using a starting point section provided on the substrate, and
a channel length of the thin film transistor is at least equal to seven times the thickness of the semiconductor film.

6. The semiconductor device according to claim 5, wherein the starting point is a hollow section provided to the substrate.

7. A semiconductor device comprising
a thin film transistor formed using a semiconductor film, wherein the semiconductor film comprises a substantially single crystal grain, and
a channel length of the thin film transistor is greater than seven times the thickness of the semiconductor film.

8. The semiconductor device of claim 7 wherein the semiconductor film comprises a single crystal grain.

9. A display device comprising the semiconductor device of claim 7.

10. The display device of claim 7 wherein said display device is a liquid crystal display device.

11. A electronic device comprising the display device of claim 7.

12. The electronic device of claim 7 wherein said display device is a liquid crystal display device.
